(19) United States
(12) Patent Application Publication
(10) Pub. No.: US 2024/0055404 A1
(43) Pub. Date: Feb. 15, 2024

(54) SEMICONDUCTOR STRUCTURE AND METHOD FOR FORMING SAME, AND MEMORY

(71) Applicant: CHANGXIN MEMORY TECHNOLOGIES, INC, Hefei City (CN)

(72) Inventor: Kaimin LV, Hefei (CN)

(21) Appl. No.: 18/156,457

(22) Filed: Jan. 19, 2023

Related U.S. Application Data
(63) Continuation of application No. PCT/CN22/13007, filed on Aug. 17, 2022.

(30) Foreign Application Priority Data
Aug. 12, 2022 (CN) 202210970472.4

(51) Int. Cl. H01L 25/065; H01L 23/00; H01L 21/56; H10B 12/00; H10B 10/00; H10B 80/00

(52) U.S. Cl. CPC H01L 25/0657; H01L 24/48; H01L 21/56; H10B 12/00; H10B 10/00; H10B 80/00; H01L 24/32; H01L 24/13; H01L 2224/32145; H01L 2224/13016; H01L 2224/48157

(57) ABSTRACT

A semiconductor structure includes a substrate, a chip set, a conductive structure and a wire. The substrate includes an external circuit. The chip set is disposed at one side of the substrate and includes a plurality of chip units that are spaced in a direction perpendicular to the substrate, and the chip units are electrically connected to each other. The conductive structure is disposed on at least a surface of at least one of the chip units. One end of the wire is connected to the conductive structure, and the other end extends outside of the chip units and is connected to the external circuit.

### CROSS-REFERENCE TO RELATED APPLICATIONS

The present application is a U.S. continuation application of International Application No. PCT/CN2022/113007, filed on Aug. 17, 2022, which claims priority to Chinese Patent Application No. 202210970472.4, filed on Aug. 12, 2022. International Application No. PCT/CN2022/113007 and Chinese Patent Application No. 202210970472.4 are incorporated herein by reference in their entireties.

### BACKGROUND

A memory is widely applied to mobile devices such as mobile phones and tablet computers due to its advantages of a small size, a high degree of integration and a fast transmission speed. In order to increase the storage capacity of a memory, a plurality of chip units are generally required to be stacked together, and each chip unit is connected to an external circuit by means of a wire. However, the wires connected to different chip units are different in length and are prone to cause delay.

It is to be noted that, information disclosed in the above Background section is merely for enhancement of understanding of the background of the disclosure, and may include information that does not constitute the prior art that is already known to a person skilled in the art.

### SUMMARY

In view of this, the disclosure provide a semiconductor structure and a method for forming the same, and a memory, to avoid signal delay, thereby enhancing product yield.

An aspect of the disclosure provides a semiconductor structure, including a substrate, a chip set, a conductive structure and a wire.

The substrate includes an external circuit.

The chip set is disposed on one side of the substrate and includes a plurality of chip units that are spaced in a direction perpendicular to the substrate, and the chip units are electrically connected to each other.

The conductive structure is disposed at a surface of at least one of the chip units.

One end of the wire is connected to the conductive structure, and the other end extends outside the chip units and is connected to the external circuit.

An aspect of the disclosure provides a method for forming a semiconductor structure. The method includes the following operations.

A substrate is provided, and the substrate includes an external circuit.

A chip set is formed on one side of the substrate. The chip set includes a plurality of chip units that are spaced in a direction perpendicular to the substrate. The chip units are electrically connected to each other.

A conductive structure is formed at a surface of at least one of the chip units.

A wire is formed. One end of the wire is connected to the conductive structure, and the other end extends outside the chip units and is connected to the external circuit.

An aspect of the disclosure provides a memory, including any of the above semiconductor structures.

It should be understood that, the above general description and the following detailed description are merely exemplary and explanatory, and cannot limit the disclosure.

### BRIEF DESCRIPTION OF THE DRAWINGS

Figures are incorporated into the specification and constitute a part of the specification. The figures illustrate embodiments in accordance with the disclosure and serve to understand the principles of the disclosure together with the specification. It is apparent that the figures in the following descriptions are merely some embodiments of the disclosure. Other figures can be obtained from a person skilled in the art according to these figures without any creative work.

FIG. 1 is a schematic diagram of a semiconductor structure in the related art.

FIG. 2 is a schematic diagram of a semiconductor structure in the related art.

FIG. 3 is a schematic diagram of a semiconductor structure according to an embodiment of the disclosure.

FIG. 4 is a schematic diagram of a conductive structure according to embodiments of the disclosure.

FIG. 5 is a schematic diagram of a connection portion according to an embodiment of the disclosure.

FIG. 6 is a schematic diagram of a connection portion according to an embodiment of the disclosure.

FIG. 7 is a schematic diagram of an insulation filling layer according to an embodiment of the disclosure.

FIG. 8 is a flowchart of a method for forming a semiconductor structure according to embodiments of the disclosure.

### DETAILED DESCRIPTION

The disclosure relates to the technical field of semiconductors, and in particular, to a semiconductor structure and a method for forming the same, and a memory.

Exemplary embodiments are described more comprehensively with reference to the drawings. However, exemplary embodiments can be implemented in various forms and should not be construed as limited to the embodiments set forth herein. In contrast, these embodiments are provided for more thorough and complete understanding of the disclosure, and to fully convey the concept of the exemplary embodiments to a person skilled in the art. The same reference numerals in the drawings denote same or similar structures, and thus detailed descriptions will be omitted. In addition, the drawings are merely schematic illustrations of the disclosure and are not necessarily drawn to scale.

Although relative terms such as “on” and “under” are used in this specification to describe a relative relationship of one component of a figure to another component, these terms are used in this specification only for convenience, for example, according to a direction of the example described in the drawings. It should be understood that, when the apparatus in a figure is turned upside down, the “on” component described will become the “under” component. When a certain structure is “on” other structures, it may mean that the certain structure is integrally formed on other structures, or that the certain structure is “directly” disposed on other structures, or that the certain structure is “indirectly” disposed on other structures by using another structure.

The terms “a”, “an”, “the”, “said” and “at least one” are used to indicate the presence of one or more elements/components/and the like. The terms “comprising/including” and “having” are used to indicate an open-ended inclusive meaning and mean that additional elements/components/and the like may be present in addition to the listed elements/components/and the like. The terms “first”, “second”, “third”, and the like are merely used as marks and are not intended to limit the number of objects.

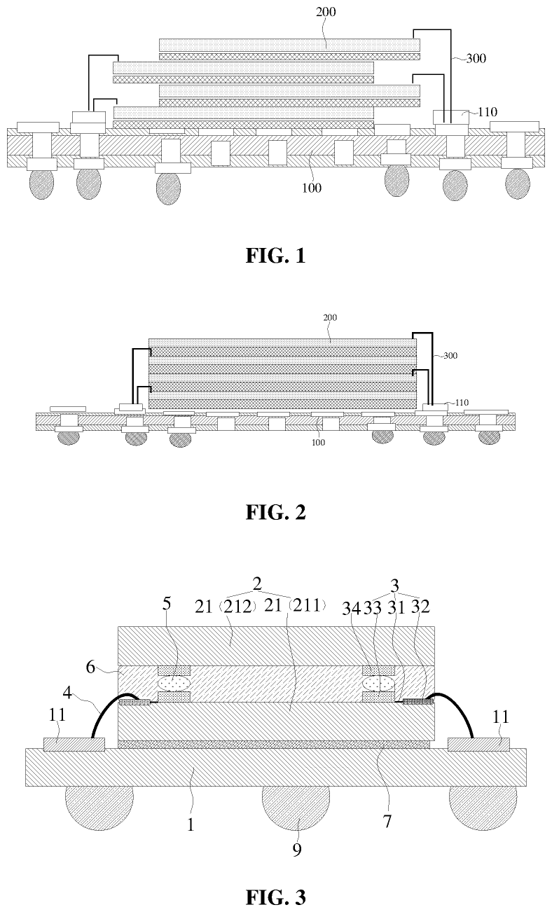

In the related art, as shown in FIG. 1 and FIG. 2, a common memory mainly includes a substrate 100 and chip units 200 disposed on the substrate 100. In order to guarantee the storage capacity of the memory, a plurality of chip units 200 are generally stacked on the substrate 100. Each chip unit 200 is required to be connected to an external circuit 110 in the substrate 100 by means of a corresponding wire 300, so as to transmit data in the chip unit 200 to the external circuit 110. However, since heights of the chip units 200 are different, the wires 300 connected to the chip units have different lengths, easily causing signal delay. Currently, signal delay is avoided generally by performing winding compensation inside or outside the chip unit 200. However, this may increase a size of the memory, and signal interference is prone to produce during winding. In addition, this is not facilitated for stacking of more chip units 200, thereby resulting in low device integration and storage capacity.

Based on this, the embodiments of the disclosure provide a semiconductor structure. FIG. 3 is a schematic diagram of a semiconductor structure according to embodiments of the disclosure. Referring to FIG. 3, the semiconductor structure may include a substrate 1, a chip set 2, a conductive structure 3 and a wire 4.

The substrate 1 may include an external circuit 11.

The chip set 2 may be disposed on one side of the substrate 1 and includes a plurality of chip units 21 that are spaced in a direction perpendicular to the substrate 1, and the chip units 21 can be electrically connected to each other.

The conductive structure 3 may be disposed on a surface of at least one of the chip units 21.

One end of the wire 4 is connected to the conductive structure 3, and the other end extends outside the chip units 21 and is connected to the external circuit 11.

In the semiconductor structure of the disclosure, the plurality of chip units 21 may be disposed in a stacked manner in a vertical direction, so that the storage capacity can be increased. In this process, by means of electrically connecting the chip units 21, data in the plurality of different chip units 21 can be transmitted to one same chip unit 21. By connecting the wire 4 and the conductive structure 3, an electrical signal in the chip unit 21 can be transmitted to the wire 4 by means of the conductive structure 3, so that the chip unit 21 can be connected to the external circuit 11 by means of the wire 4, so as to achieve signal transmission. In this process, signals in the plurality of chip units 21 in the chip set 2 can be simultaneously transmitted to the external circuit 11 by using one wire 4, so that signal transmission delay of different chip units 21 in the same chip set 2 can be avoided. In addition, winding may also be avoided, which facilitates the reduction of the size of the device, thereby avoiding signal interference. In addition, since the chip units 21 are spaced in the direction perpendicular to the substrate 1, an accommodation space can be reserved for the wire 4, so as to prevent the wire 4 from fracturing, thereby enhancing product yield.

Details of the semiconductor structure of the disclosure are described below.

As shown in FIG. 4 to FIG. 6, the substrate 1 may be of a flat-plate structure, which may be a rectangle, a circle, an ellipse, a polygon, or an irregular shape. A material of the substrate may be a semiconductor material, for example, silicon, but is not limited to silicon or other semiconductor materials, and the shape and material of the substrate 1 are not specifically limited thereto.

The substrate 1 may include a central area and a peripheral area. The central area and the peripheral area may be arranged adjacently. The peripheral area may surround the periphery of the central area. The center are may be used to form the chip set 2, and the peripheral area may be used to form the external circuit 11. For example, the central area may be a circular area, a rectangular area, or an irregular shape area. Also, the central area may be an area with other shape, which is not specifically limited herein. The peripheral area may be an annular area and may surround the periphery of the central area. The peripheral area may be a circle annular area, a rectangular annular area, or an annular of other shape, which is not enumerated herein.

The chip set 2 may be disposed on one side of the substrate 1 and may be applied to an integrated circuit. For example, the chip set may be applied to a Dynamic Random Access Memory (DRAM) or a Static Random Access Memory (SRAM). In order to achieve a low drive voltage, the size of the DRAM or the SRAM is required to be reduced as much as possible. The chip unit 21 is a core component of the DRAM or the SRAM. In order to reduce the size of the DRAM or the SRAM while the storage capacity is guaranteed, the plurality of chip units 21 may be disposed in a stacked manner in the direction perpendicular to the substrate 1, so as to form the chip set 2. For example, the number of the chip units 21 in the chip set 2 may be 2, 3, 4, 5, 6, or 7. Also, there may be other number of chip units, which is not specifically limited herein.

In some embodiments of the disclosure, all the chip units 21 in the chip set 2 can be electrically connected to each other, so that the data in the plurality of chip units 21 can be transmitted mutually, and the data in the plurality of different chip units 21 can be transmitted to one same chip unit 21. Therefore, in the subsequent process, the electrical signals in the chip units 21 in the chip set 2 can be simultaneously transmitted to the wire 4 by means of the conductive structure 3, and the chip unit 21 can be connected to the external circuit 11 by using the wire 4, so as to achieve signal transmission.

In some embodiments of the disclosure, all the chip units 21 in the chip set 2 may be spaced in the direction perpendicular to the substrate 1, so that an accommodation space can be reserved for the wire 4 that is subsequently formed, so as to prevent the wire 4 from fracturing, thereby enhancing the product yield. For example, the chip units 21 may be equidistantly spaced in the direction perpendicular to the substrate 1. For example, two adjacent ones of the chip units 21 may be spaced by a preset distance. Alternatively, the distance between the chip units 21 may not be exactly the same. For example, at least one of the distances between two adjacent ones of the chip units 21 does not equal the others.

In some embodiments of the disclosure, the preset distance may range from 10 um to 150 um. For example, the preset distance may be 10 um, 40 um, 70 um, 100 um, 130 um, or 150 um. Also, the preset distance may be other values, which is not enumerated herein.

In an exemplary embodiment of the disclosure, the chip unit 21 may be of a sheet structure. The shape of the chip unit may be a rectangle, a circle, an ellipse, or an irregular shape, which is not specifically limited herein. Thicknesses of the chip units 21 may be the same or different, which is not specifically limited herein. The thickness of the chip unit 21 may range from 40 um to 80 um, for example, 40 um, 50 um, 60 um, 70 um, or 80 um. Also, the chip unit may be of other thickness, which is not enumerated herein.

In some embodiments of the disclosure, the chip units 21 in the chip set 2 may have the same thicknesses. For example, the thicknesses of the chip units 21 may be 50 um; alternatively, the thicknesses of the chip units 21 may be 60 um; alternatively, the thicknesses of the chip units 21 may be 70 um. Also, the chip unit 21 may have other thickness, which is not enumerated herein.

In an exemplary embodiment of the disclosure, the chip unit 21 may include a wafer and a circuit module disposed on a surface of the wafer. The chip set 2 may include two chip units 21. For ease of distinguishing, the two chip units 21 may respectively defined as a first chip unit 211 and a second chip unit 212. The second chip unit 212 may be located at a side of the first chip unit 211 away from the substrate 1. The first chip unit 211 and the second chip unit 212 may be in mirror arrangement, That is, the first chip unit 211 is identical to the second chip unit 212. The circuit module of the first chip unit 211 is disposed opposite to the circuit module of the second chip unit 212.

The conductive structure 3 may be disposed on a surface of at least one of the chip units 21. For example, the conductive structure 3 may be disposed on a surface of any one of the chip units 21 in the chip set 2 and may be connected to the circuit module on the surface of the chip unit 21 in a contact manner. The circuit module of the chip unit 21 may be electrically led out by means of the conductive structure 3, so as to transmit a data signal in the chip unit 21 to the external circuit 11 by means of the conductive structure 3.

Preferably, the conductive structure 3 may be disposed on a surface of the chip unit 21 closest to the substrate 1 in the chip set 2. In this case, a length of the wire 4 that is subsequently connected to the conductive structure 3 can be shortened to the greatest extent, so as to shorten the signal transmission duration that the signal in the chip unit 21 is transmitted to the external circuit 11, thereby facilitating the enhancement of signal transmission efficiency. In addition, materials required for manufacturing the wire 4 can also be saved, thereby reducing manufacturing cost. For example, when the chip set 2 includes the first chip unit 211 and the second chip unit 212 that are in mirror arrangement, and the second chip unit 212 may be located at the side of the first chip unit 211 away from the substrate 1, the conductive structure 3 may be disposed on the surface of the first chip unit 211 close to the second chip unit 212.

In some embodiments of the disclosure, during the mass production of the chip units 21, to simplify the process, the conductive structure 3 may be formed on a surface of each chip unit 21. The conductive structure 3 of each chip unit 21 is connected to the circuit module of the corresponding chip unit 21 in a contact manner. In the chip set 2, the wire 4 subsequently formed may be connected to the conductive structure 3 on the surface of any one of the chip units 21.

In an exemplary embodiment of the disclosure, the conductive structure 3 may include a redistribution layer 31, a connection pad 32 and a first conductive bump 33.

The redistribution layer 31 may be disposed on the surface of the chip unit 21. The redistribution layer may be a thin film that is formed on the surface of the chip unit 21, or may be a coating that is formed on the surface of the chip unit 21. The form of the redistribution layer 31 is not specifically limited herein. A material of the redistribution layer 31 may be a conductive material. For example, the material may be a metal or other conductive material. The redistribution layer 31 may be formed on the surface of the chip unit 21 by means of vacuum evaporation, magnetron sputtering, chemical vapor deposition, physical vapor deposition, atomic layer deposition or the like. Also, the redistribution layer 31 may be formed in other manners, and the manner of forming the redistribution layer 31 is not specifically limited herein.

The connection pad 32 may be disposed on the surface of the chip unit 21, and may be made of a conductive material. For example, the material of the connection pad may be gold, silver, copper, aluminum, tungsten, or the like. In some embodiments of the disclosure, the connection pad 32 may be a welding pad that is formed on the surface of the chip unit 21, and may be connected to the redistribution layer 31 by means of welding. In some other embodiments of the disclosure, the connection pad 32 may be a thin film that is formed on the surface of the chip unit 21, or may be a coating that is formed on the surface of the chip unit 21, and the form of the connection pad 32 is not specifically limited herein. The connection pad 32 may be formed on the surface of the chip unit 21 by means of vacuum evaporation, magnetron sputtering, chemical vapor deposition, physical vapor deposition, atomic layer deposition or the like. Also, the connection pad 32 may be formed in other manners, and the manner of forming the connection pad 32 is not specifically limited herein.

It is to be noted that, in order to facilitate the connection between the connection pad 32 and the subsequently-formed wire 4 and prevent the wire 4 from winding inside the chip unit 21, the connection pad 32 may be disposed on a side of the redistribution layer 31 close to an edge of the chip unit 21, and may be connected to the side of the redistribution layer 31 close to an edge of the chip unit 21 in a contact manner.

The first conductive bump 33 may be disposed on the surface of the chip unit 21, and the orthographic projection of the first conductive bump on the substrate 1 does not overlap with the orthographic projection of the connection pad 32 on the substrate 1. The first conductive bump 33 can be connected to the circuit module of the chip unit 21 in a contact manner. In addition, the first conductive bump 33 can also be connected to the redistribution layer 31 in a contact manner. By means of the first conductive bump 33, the data signal in the circuit module of the chip unit 21 can be transmitted to the connection pad 32 by means of the redistribution layer 31, so as to subsequently transmit the data signal to the external circuit 11 by means of the wire 4 connected to the connection pad 32.

In some embodiments of the disclosure, the first conductive bump 33 may be made of a conductive material. For example, the material may be gold, silver, copper, aluminum, tungsten, or the like. In some embodiments of the disclosure, the first conductive bump 33 may be a welding pad that is formed on the surface of the chip unit 21 and may be connected to the redistribution layer 31 and the external circuit 11 of the chip unit 21 by means of welding. In some other embodiments of the disclosure, the first conductive bump 33 may be a thin film that is formed on the surface of the chip unit 21, or may be a coating that is formed on the surface of the chip unit 21, and the form of the first conductive bump 33 is not specifically limited herein. The first conductive bump 33 may be formed on the surface of the chip unit 21 by means of vacuum evaporation, magnetron sputtering, chemical vapor deposition, physical vapor deposition, atomic layer deposition or the like. Also, the first conductive bump 33 may be formed in other manners, and the manner of forming the first conductive bump 33 is not specifically limited herein.

In some embodiments of the disclosure, both a surface of the first chip unit 211 and a surface of the second chip unit 212 may be provided with the conductive structures 3. That is to say, the surface of the first chip unit 211 may be provided with the redistribution layers 31, the connection pads 32 and the first conductive bumps 33; and the surface of the second chip unit 212 may be provided with the redistribution layers 31, the connection pads 32 and the first conductive bumps 33. For ease of distinguishing, the first conductive bump 33 on the surface of the second chip unit 212 may be defined as a second conductive bump 34. The second conductive bump 34 may be disposed on the surface of the second chip unit 212 close to the first chip unit 211, and is disposed oppositely to the first conductive bump 33 of the first chip unit 211. Meanwhile, for ease of subsequent assembling, during the manufacture, the first chip unit 211 and the second chip unit 212 may be maintained consistent in term of structures. That is to say, when the first chip unit 211 and the second chip unit 212 are in mirror arrangement, the first conductive bump 33 on the surface of the first chip unit 211 is distributed oppositely to the second conductive bump 34 on the surface of the second chip unit 212. Meanwhile, the redistribution layer 31 on the surface of the first chip unit 211 is distributed oppositely to the redistribution layer 31 on the surface of the second chip unit 212, and the connection pad 32 on the surface of the first chip unit 211 is also distributed oppositely to the connection pad 32 on the surface of the second chip unit 212.

One end of the wire 4 may be connected to the conductive structure 3, and the other end may extend outside the chip units 21 and be connected to the external circuit 11 on the substrate 1. For example, the wire 4 may be connected to the connection pad 32 in a contact manner. The data signal in the chip unit 21 may be transmitted to the external circuit 11 by means of the wire 4, the connection pad 32, the redistribution layer 31 and the first conductive bump 33. In some embodiments of the disclosure, two ends of the wire 4 may be respectively connected to the external circuit 11 on the substrate 1 and the conductive structure 3 by welding. For example, one end of the wire 4 may be welded with the connection pad 32 of the conductive structure 3, and the other end of the wire is welded with the external circuit 11.

In some embodiments of the disclosure, the wire 4 may be connected to the conductive structure 3 on the surface of one of the chip units 21 in the chip set 2. Since the chip units 21 in the chip set 2 are electrically connected to each other, data in the plurality of different chip units 21 can be transmitted to one same chip unit 21. By connecting the wire 4 and the conductive structure 3 on the surface of such a chip unit 21, an electrical signal in the chip unit 21 can be transmitted to the wire 4 by means of the conductive structure 3, so that the chip unit 21 can be connected to the external circuit 11 by means of the wire 4, so as to achieve signal transmission. In this process, signals in the plurality of chip units 21 in the chip set 2 can be simultaneously transmitted to the external circuit 11 by using one wire 4, so that signal transmission delay of different chip units 21 in the dame chip set 2 can be avoided.

The wire 4 may be made of a conductive material. For example, the wire may be made of a metal material such as gold, silver, copper and aluminum, or may be alloy composed of two or more materials. Also, the wire may be made of other metals with good conductive performance, which is not specifically limited herein. Also, the wire 4 may be made of other materials, for example, may be a non-metallic material such as polysilicon, which is not enumerated herein.

In an exemplary embodiment of the disclosure, the chip set 2 in the disclosure may further include a connection portion 5. The connection portion 5 may be disposed between two adjacent ones of the chip units 21, and may be connected to the first conductive bumps 33 on the surfaces of two adjacent ones of the chip units 21 in a contact manner. For example, where the chip set 2 includes first chip unit 211 and the second chip unit 212, the connection portion 5 may be located between the first conductive bump 33 and the second conductive bump 34 and may be connected to the first conductive bump 33 and the second conductive bump 34 in a contact manner. The connection portion 5 may be connected to the second conductive bump 34 on the surface of the second chip unit 212 by welding, and then, the first conductive bump 33 on the surface of the first chip unit 211 is welded with the connection portion 5.

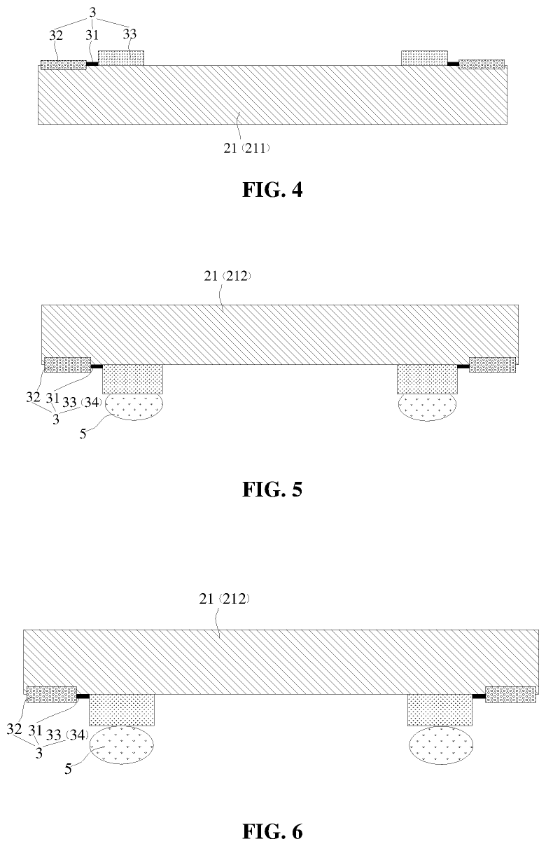

In some embodiments of the disclosure, the connection portion 5 may be made of a conductive material. For example, the material may be a soldering material that is composed of at least one of materials such as tin, lead, silver, copper, nickel, zinc, bismuth, indium, gold, cadmium, germanium or silicon. A shape of the connection portion may be hemispherical, spherical, ellipsoidal, cylindrical, cuboid, or the like (as shown in FIG. 5 and FIG. 6). The first chip unit 211 may be electrically connected to the second chip unit 212 by means of the first conductive bump 33, the connection portion 5 and the second conductive bump 34.

It is to be noted that, a “sandwich” structure that is composed of the first conductive bump 33, the connection portion 5 and the second conductive bump 34 is disposed between two adjacent ones of the chip units 21. Two adjacent ones of the chip units 21 in the chip set may be electrically connected to each other by means of the “sandwich” structure between the two adjacent ones of the chip units 21.

For example, the first conductive bump 33 and the connection portion 5 may be disposed on the surface of the first chip unit 211 on which the circuit module is disposed; and only the second conductive bump 34 is disposed on the surface of the second chip unit 212 on which the circuit module is disposed. Alternatively, the second conductive bump 34 and the connection portion 5 are disposed on the surface of the second chip unit 212 on which the circuit module is disposed; and only the first conductive bump 33 is disposed on the surface of the first chip unit 211 on which the circuit module is disposed.

Alternatively, it is to be noted that, the conductive structure 3 may be disposed on each of two adjacent one of the chip units 21. For example, the first conductive bump 33 and the connection portion 5 are disposed on the first chip unit 211, and the connection portion 5 and the second conductive bump 34 are disposed on the second chip unit 212. The orthographic projection of the first conductive bump 33 and the connection portion 5 on the first chip unit 211 on the substrate does not overlap with the orthographic projection of the connection portion 5 and the second conductive bump 34 on the second chip unit 212 on the substrate 1. Therefore, the first chip unit 211 can be electrically connected to the second chip unit 212 by means of the two connection portions 5 between the first chip unit 211 and the second chip unit 212.

Alternatively, it is to be noted that, the conductive structure 3 may be disposed on each of two adjacent ones of the chip units 21. For example, the first conductive bump 33 and the second conductive bump 34 that are distributed in a staggered manner are respectively disposed on the first chip unit 211 and the second chip unit 212. Therefore, the first chip unit 211 can be electrically connected to the second chip unit 212 directly by means of the first conductive bump 33 and the second conductive bump 34.

In some embodiments of the disclosure, the first conductive bump 33, the connection portion 5 and the second conductive bump 34 may separate the adjacent chip units 21 by a preset distance. For example, where the chip set 2 includes the first chip unit 211 and the second chip unit 212, the first conductive bump 33, the connection portion 5 and the second conductive bump 34 may separate the first chip unit 211 and the second chip unit 212 by the preset distance. For the preset distance, refer to the preset distance in the above embodiments, which is not described herein again. It is to be noted that, the preset distance may be greater than longitudinal spacing required for the bending of the wire 4. The end of the wire 4 that is connected to the connection pad 32 can be bent at the preset distance that the first chip unit 211 is spaced apart from the second chip unit 212, so that the wire 4 can be prevented from being fractured, thereby enhancing product yield.

In an exemplary embodiment of the disclosure, as shown in FIG. 3, the semiconductor structure of the disclosure may further include an insulation filling layer 6. The adjacent chip units 21 may be insulated and isolated by the insulation filling layer 6, so that signal crosstalk or coupling between the chip units 21 can be avoided.

In an exemplary embodiment of the disclosure, a material of the insulation filling layer 6 may be an insulating adhesive or a packaging adhesive. External water and oxygen can be isolated by means of the insulation filling layer 6, so that the external water and oxygen can be prevented from entering into the chip unit 21, so as to prevent the water and oxygen from corroding the internal structure of the chip unit 21, thereby prolonging the service life of the chip unit 21.

In some embodiments of the disclosure, the insulation filling layer 6 may fill up a gap between adjacent chip units 21, so that the gap between the adjacent chip units 21 can be supported by means of the insulation filling layer 6. In addition, stress between the two adjacent chip units 21 can be balanced, so that the possibility of the fracturing of the chip units 21 due to external force can be reduced, thereby enhancing product yield.

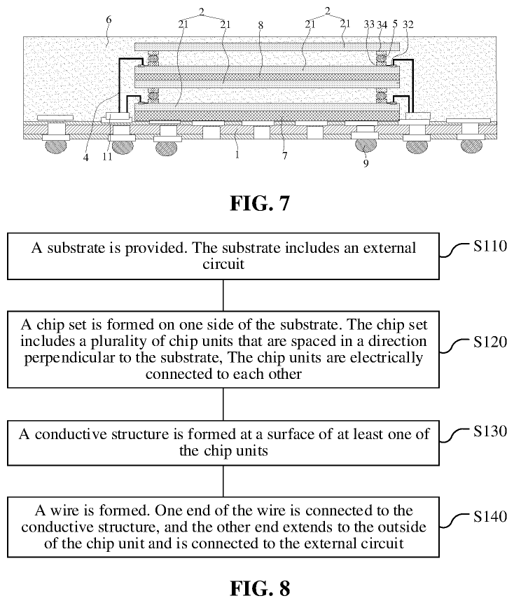

In some embodiments of the disclosure, as shown in FIG. 7, the insulation filling layer 6 in the chip set 2 may be thick. The chip units 21 may be embedded in the insulation filling layer 6. For example, after the chip set 2 is formed, the insulation filling layer 6 may be formed on a surface of a structure that is jointly formed by the substrate 1 and the chip set 2. The insulation filling layer 6 can fill up all the gaps between the adjacent chip units 21, and wrap sidewalls of every chip unit 21, so that all-round isolation protection of the chip units 21 can be achieved.

In some other embodiments of the disclosure, the insulation filling layer 6 may include a plurality of insulation layers that are spaced. The number of the insulation layers may match the number of gaps between the chip units 21. For example, in a same chip set 2, the number of the insulation layers may be 1 less than the number of the chip units 21. The insulation layers may be distributed between the two adjacent chip units 21 in a one-to-one correspondence. A thickness of the insulation layer may equal the spacing between chip units 21 that are adjacent to the insulation layer. That is to say, the insulation layer may fill up the gap between the chip units 21 that are adjacent to the insulation layer.

It is to be noted that, after the structure that is jointly formed by the insulation layers and chip sets 2 is fixed on the substrate 1, an insulation material may further continuously fill a surface of a structure that is jointly formed by the insulation layers, the chip sets 2 and the substrate 1, so as to embed the chip sets 2 into the insulation material. The insulation material together with the insulation layers may form the insulation filling layer 6. The insulation material may be the same or different from the material of the insulation layer, which is not specifically limited herein. For example, both the insulation material and the material of the insulation layer may be an insulating adhesive or a packaging adhesive; alternatively, one of the insulation material and the material of the insulation layer is an insulating adhesive, and the other is a packaging adhesive.

In an exemplary embodiment of the disclosure, in order to further increase the storage capacity, there may be a plurality of chip sets 2. The plurality of chip sets 2 may be distributed in a laminated manner in the direction perpendicular to the substrate 1. For example, the number of the chip sets 2 may be 2, 3, 4, 5, 6, or 7. Also, there may be other number of chip sets, which is not specifically limited herein.

In some embodiments of the disclosure, the number of chip units 21 in different chip sets 2 may be the same. For example, the number of the chip units 21 in each chip set 2 may be 2; alternatively, the number of the chip units 21 in each chip set 2 may be 3; and alternatively, the number of the chip units 21 in each chip set 2 may be 4. Also, there may be other number of chip units 21 in the chip sets 2, which is not enumerated herein.

In some other embodiments of the disclosure, the number of the chip units 21 in different chip sets 2 may be different. For example, the number of the chip units 21 in some of the chip sets 2 is 2, and the number of the chip units 21 in other chip sets 2 is 3; and for another example, the number of the chip units 21 in some of the chip sets 2 is 3, and the number of the chip units 21 in other chip sets 2 is 4. Also, there may be other number of chip units 21 in the chip sets 2, which is not enumerated herein.

In some embodiments of the disclosure, the chip sets 2 may be disposed with each other in an insulated manner, so that data crosstalk among different chip sets 2 can be avoided. Each chip set 2 has the corresponding conductive structure 3 and the wire 4, so that data in different chip sets 2 may be transmitted to the external circuit 11 by means of different wires 4.

In some embodiments of the disclosure, the semiconductor structure of the disclosure may further include a plurality of packaging layers 8. The packaging layers 8 may be disposed at gaps between the chip sets 2 in a one-to-one correspondence and fill up the gaps between the chip sets 2. External water and oxygen can be isolated by means of the packaging layers 8 and thus be prevented from entering the chip set 2, so as to prevent the water and oxygen from corroding the internal structure of the chip set 2, thereby prolonging the service life of the chip set 2.

In an exemplary embodiment of the disclosure, a material of the packaging layer 8 may be an insulating non-conductive adhesive or packaging adhesive. The adjacent chip sets 2 can be insulated and isolated by means of the packaging layer 8, so that signal crosstalk or coupling between the chip sets 2 can be avoided.

In some embodiments of the disclosure, the number of the packaging layers 8 may match the number of the chip sets 2. For example, the number of the packaging layers 8 may be 1 less than the number of the chip sets 2. The packaging layers 8 may be distributed between two adjacent chip sets 2 in a one-to-one correspondence. The orthographic projection of the packaging layer 8 on the substrate 1 may overlap with at least the orthographic projection of the chip set 2 on the substrate 1. It is to be noted that, the packaging layers 8 may also be connected together to completely wrap the chip sets 2, so that the all-round packaging of the chip sets 2 can be achieved.

In an exemplary embodiment of the disclosure, the semiconductor structure of the disclosure may further include an adhesive layer 7. The adhesive layer 7 may be disposed between the substrate 1 and the chip set 2 that is closest to the substrate 1. A material of the adhesive layer 7 may be a conductive adhesive. The chip set 2 that is closest to the substrate 1 may be pasted on the surface of the substrate 1 by means of the adhesive layer 7, so as to prevent the chip set 2 from swaying relative to the substrate 1. It is to be noted that, the orthographic projection of the adhesive layer 7 on the substrate 1 does not overlap with the external circuit 11. That is to say, the external circuit 11 may be exposed from the adhesive layer 7, so as to facilitate the connection between the external circuit 11 and the wire 4. For example, the adhesive layer 7 may be located in a middle area of the substrate 1, and the orthographic projection of the adhesive layer on the substrate 1 may mutually overlap with the orthographic projection of the chip set 2 closest to the substrate 1 on the substrate 1.

In embodiments of the disclosure, the semiconductor structure may further include a plurality of solder balls 9. The solder balls 9 may be disposed on a side of the substrate 1 away from the chip set 2. The electrical signal in the chip unit 21 may be transmitted to an external circuit by means of the solder balls 9.

Embodiments of the disclosure further provide a method for forming a semiconductor structure. FIG. 8 is a flowchart of a method for forming a semiconductor structure. Referring to FIG. 8, the formation method may include S110 to S140.

At S110, a substrate is provided, and the substrate includes an external circuit.

At S120, a chip set is formed at a side of the substrate. The chip set includes a plurality of chip units that are spaced in a direction perpendicular to the substrate. The chip units are electrically connected to each other.

At S130, a conductive structure is formed on a surface of at least one of the chip units.

At S140, a wire is formed. One end of the wire is connected to the conductive structure, and the other end extends outside the chip units and is connected to the external circuit.

According to the method for forming a semiconductor structure in the disclosure, the plurality of chip units 21 can be disposed in a stacked manner in a vertical direction, so that the storage capacity can be increased. In this process, by means of electrically connecting the chip units 21, data in different chip units 21 can be transmitted to one same chip unit 21. By connecting the wire 4 to the conductive structure 3, an electrical signal in the chip unit 21 can be transmitted to the wire 4 by means of the conductive structure 3, so that the chip unit 21 can be connected to the external circuit 11 by means of the wire 4, so as to achieve signal transmission. In this process, signals in the plurality of chip units 21 in the chip set 2 can be simultaneously transmitted to the external circuit 11 by using one wire 4, so that signal transmission delay of different chip units 21 in the dame chip set 2 can be avoided. In addition, winding may also be avoided, which facilitates the reduction of the size of the device, thereby avoiding signal interference. In addition, since the chip units 21 are spaced in the direction perpendicular to the substrate 1, an accommodation space can be reserved for the wire 4, so as to prevent the wire 4 from fracturing, thereby enhancing product yield.

The method for forming a semiconductor structure according to embodiments of the disclosure are described in detail below.

As shown in FIG. 8, at S110, the substrate is provided, and the substrate includes the external circuit.

As shown in FIG. 4 to FIG. 6, the substrate 1 may be of a flat-plate structure, which may be a rectangle, a circle, an ellipse, a polygon, or an irregular shape. A material of the substrate may be a semiconductor material, for example, silicon, but is not limited to the silicon or other semiconductor materials, and the shape and material of the substrate 1 are not specifically limited thereto.

The substrate 1 may include a central area and a peripheral area. The central area and the peripheral area may be arranged adjacently. The peripheral area may surround the periphery of the central area. The center are may be used to form the chip set 2, and the peripheral area may be used to form the external circuit 11. For example, the central area may be a circular area, a rectangular area, or an irregular shape area. Also, the central area may be an area with other shape, which is not specifically limited herein. The peripheral area may be an annular area and may surround the periphery of the central area. The peripheral area may be a circle annular area, a rectangular annular area, or an annular area of other shape, which is not enumerated herein.

As shown in FIG. 8, at S120, the chip set is formed on one side of the substrate. The chip set includes the plurality of chip units that are spaced in the direction perpendicular to the substrate. The chip units are electrically connected to each other.

The chip set 2 may be disposed on one side of the substrate 1 and may be applied to an integrated circuit. For example, the chip set may be applied to a DRAM or an SRAM. In order to achieve a low drive voltage, the size of the DRAM or the SRAM is required to be reduced as much as possible. The chip unit 21 is a core component of the DRAM or the SRAM. In order to reduce the size of the DRAM or the SRAM while the storage capacity is guaranteed, the plurality of chip units 21 may be disposed in a stacked manner in the direction perpendicular to the substrate 1, so as to form the chip set 2. For example, the number of the chip units 21 in the chip set 2 may be 2, 3, 4, 5, 6, or 7. Also, there may be other number of chip units, which is not specifically limited herein.

In some embodiments of the disclosure, all the chip units 21 in the chip set 2 can be electrically connected to each other, so that the data in the plurality of chip units 21 can be transmitted mutually, and the data in the plurality of different chip units 21 can be transmitted to one same chip unit 21. Therefore, in the subsequent process, the electrical signals in the chip units 21 in the chip set 2 can be transmitted to the wire 4 by means of the conductive structure 3, and the chip unit 21 can be connected to the external circuit 11 by using the wire 4, so as to achieve signal transmission.

In some embodiments of the disclosure, all the chip units 21 in the chip set 2 may be spaced in the direction perpendicular to the substrate 1, so that an accommodation space can be reserved for the wire 4 that is subsequently formed, so as to prevent the wire 4 from fracturing, thereby enhancing the product yield. For example, the chip units 21 may be equidistantly spaced in the direction perpendicular to the substrate 1. For example, two adjacent ones of the chip units 21 may be spaced by a preset distance. Alternatively, the distance between the chip units 21 may not be exactly the same. For example, at least one of the distances between two adjacent ones of the chip units 21 does not equal the others.

In some embodiments of the disclosure, the preset distance may range from 10 um to 150 um. For example, the preset distance may be 10 um, 40 um, 70 um, 100 um, 130 um, or 150 um. Also, the preset distance may be other values, which is not enumerated herein.

In an exemplary embodiment of the disclosure, the chip unit 21 may be of a sheet structure. The shape of the chip unit may be a rectangle, a circle, an ellipse, or an irregular shape, which is not specifically limited herein. Thicknesses of the chip units 21 may be the same or different, which is not specifically limited herein. The thickness of the chip unit 21 may range from 40 um to 80 um, for example, may be 40 um, 50 um, 60 um, 70 um, or 80 um. Also, the chip unit may be of other thickness, which is not enumerated herein.

In some embodiments of the disclosure, the chip units 21 in the chip set 2 may have the same thicknesses. For example, the thicknesses of the chip units 21 may be 50 um; alternatively, the thicknesses of the chip units 21 may be 60 um; alternatively, the thicknesses of the chip units 21 may be 70 um. Also, the chip unit 21 may have other thickness, which is not enumerated herein.

In an exemplary embodiment of the disclosure, the chip unit 21 may include a wafer and a circuit module disposed on a surface of the wafer. The chip set 2 may include two chip units 21. For ease of distinguishing, the two chip units 21 may respectively defined as a first chip unit 211 and a second chip unit 212. The second chip unit 212 may be located at a side of the first chip unit 211 away from the substrate 1. The first chip unit 211 and the second chip unit 212 may be in mirror arrangement. That is, the first chip unit 211 is identical to the second chip unit 212. The circuit module of the first chip unit 211 is disposed opposite to the circuit module of the second chip unit 212.

As shown in FIG. 8, at S130, the conductive structure is formed on a surface of at least one of the chip units.

The conductive structure 3 may be disposed on the surface of at least one of the chip units 21. For example, the conductive structure 3 may be disposed on the surface of any one of the chip units 21 in the chip set 2, and may be connected to the circuit module on the surface of the chip unit 21 in a contact manner. The circuit module of the chip unit 21 may be electrically led out by means of the conductive structure 3, so as to transmit a data signal in the chip unit 21 to the external circuit 11 by means of the conductive structure 3.

Preferably, the conductive structure 3 may be disposed on a surface of the chip unit 21 closest to the substrate 1 in the chip set 2. In this case, a length of the wire 4 that is subsequently connected to the conductive structure 3 can be shortened to the greatest extent, so as to shorten the signal transmission duration that the signal in the chip unit 21 is transmitted to the external circuit 11, thereby facilitating the enhancement of signal transmission efficiency. In addition, materials required for manufacturing the wire 4 can also be saved, thereby reducing manufacturing cost. For example, when the chip set 2 includes the first chip unit 211 and the second chip unit 212 that are in mirror arrangement, and the second chip unit 212 may be located at the side of the first chip unit 211 away from the substrate 1, the conductive structure 3 may be disposed on the surface of the first chip unit 211 close to the second chip unit 212.

In some embodiments of the disclosure, during the mass production of the chip units 21, to simplify the process, the conductive structure 3 may be formed on a surface of each chip unit 21. The conductive structure 3 of each chip unit 21 is connected to the circuit module of the corresponding chip unit 21 in a contact manner. In the chip set 2, the wire 4 subsequently formed may be connected to the conductive structure 3 of any one of the chip units 21.

In an exemplary embodiment of the disclosure, the operation (i.e., S130) of forming the conductive structure 3 on the surface of at least one of the chip units 21 may include S210 to S230.

At S210, a redistribution layer 31 is formed on the surface of at least one of the chip units 21.

The redistribution layer 31 may be disposed on the surface of the chip unit 21. The redistribution layer may be a thin film that is formed on the surface of the chip unit 21, or may be a coating that is formed on the surface of the chip unit 21. The form of the redistribution layer 31 is not specifically limited herein. A material of the redistribution layer 31 may be a conductive material. For example, the material may be a metal or other conductive material. The redistribution layer 31 may be formed on the surface of the chip unit 21 by means of vacuum evaporation, magnetron sputtering, chemical vapor deposition, physical vapor deposition, atomic layer deposition or the like. Also, the redistribution layer 31 may be formed in other manners, and the manner of forming the redistribution layer 31 is not specifically limited herein.

At S220, a connection pad 32 is formed on the surface of the chip unit 21 on which the redistribution layer 31 is formed. The connection pad 32 is connected to a side of the redistribution layer 31 close to an edge of the chip unit 21, and the wire 4 is connected to the connection pad 32 in a contact manner.

The connection pad 32 may be disposed on the surface of the chip unit 21, and may be made of a conductive material. For example, the material of the connection pad may be gold, silver, copper, aluminum, tungsten, or the like. In some embodiments of the disclosure, the connection pad 32 may be a welding pad that is formed on the surface of the chip unit 21, and may be connected to the redistribution layer 31 by means of welding. In some other embodiments of the disclosure, the connection pad 32 may be a thin film that is formed on the surface of the chip unit 21, or may be a coating that is formed on the surface of the chip unit 21, and the form of the connection pad 32 is not specifically limited herein. The connection pad 32 may be formed on the surface of the chip unit 21 by means of vacuum evaporation, magnetron sputtering, chemical vapor deposition, physical vapor deposition, atomic layer deposition or the like. Also, the connection pad 32 may be formed in other manners, and the manner of forming the connection pad 32 is not specifically limited herein.

It is to be noted that, in order to facilitate the connection between the connection pad 32 and the subsequently-formed wire 4 and prevent the wire 4 from winding inside the chip unit 21, the connection pad 32 may be disposed on a side of the redistribution layer 31 close to an edge of the chip unit 21, and may be connected to the side of the redistribution layer 31 close to an edge of the chip unit 21 in a contact manner.

At S230, a first conductive bump 33 is formed on the surface of the chip unit 21 on which the redistribution layer 31 is formed. The first conductive bump 33 is connected to the redistribution layer 31 in a contact manner. The orthographic projection of the first conductive bump 33 on the substrate 1 does not overlap with the orthographic projection of the connection pad 32 on the substrate 1.

The first conductive bump 33 may be disposed on the surface of the chip unit 21, and the orthographic projection of the first conductive bump on the substrate 1 does not overlap with the orthographic projection of the connection pad 32 on the substrate 1. The first conductive bump 33 can be connected to the circuit module of the chip unit 21 in a contact manner. In addition, the first conductive bump 33 can also be connected to the redistribution layer 31 in a contact manner. By means of the first conductive bump 33, the data signal in the circuit module of the chip unit 21 can be transmitted to the connection pad 32 by means of the redistribution layer 31, so as to subsequently transmit the data signal to the external circuit 11 by means of the wire 4 connected to the connection pad 32.

In some embodiments of the disclosure, the first conductive bump 33 may be made of a conductive material. For example, the material may be gold, silver, copper, aluminum, tungsten, or the like. In some embodiments of the disclosure, the first conductive bump 33 may be a connection portion 5 that is formed on the surface of the chip unit 21, and may be connected to the redistribution layer 31 and the external circuit 11 of the chip unit 21 by means of welding. In some other embodiments of the disclosure, the first conductive bump 33 may be a thin film that is formed on the surface of the chip unit 21, or may be a coating that is formed on the surface of the chip unit 21, and the form of the first conductive bump 33 is not specifically limited herein. The first conductive bump 33 may be formed on the surface of the chip unit 21 by means of vacuum evaporation, magnetron sputtering, chemical vapor deposition, physical vapor deposition, atomic layer deposition or the like. Also, the first conductive bump 33 may be formed in other manners, and the manner of forming the first conductive bump 33 is not specifically limited herein.

In some embodiments of the disclosure, the method for forming a semiconductor structure may further include the following operation.

At S150, a second conductive bump 34 is formed on a surface of the second chip unit 212 close to the first chip unit 211. The second conductive bump 34 is disposed oppositely to the first conductive bump 33.

In some embodiments of the disclosure, both a surface of the first chip unit 211 and a surface of the second chip unit 212 may be provided with the conductive structures 3. That is to say, the surface of the first chip unit 211 may be provided with the redistribution layers 31, the connection pads 32 and the first conductive bumps 33; and the surface of the second chip unit 212 may be provided with the redistribution layers 31, the connection pads 32 and the first conductive bumps 33. For ease of distinguishing, the first conductive bump 33 on the surface of the second chip unit 212 may be defined as a second conductive bump 34. The second conductive bump 34 may be disposed on the surface of the second chip unit 212 close to the first chip unit 211, and is disposed oppositely to the first conductive bump 33 of the first chip unit 211. Meanwhile, for ease of subsequent assembling, during the manufacture, the first chip unit 211 and the second chip unit 212 may be maintained consistent in term of structures. That is to say, when the first chip unit 211 and the second chip unit 212 are in mirror arrangement, the first conductive bump 33 on the surface of the first chip unit 211 is distributed oppositely to the second conductive bump 34 on the surface of the second chip unit 212. Meanwhile, the redistribution layer 31 on the surface of the first chip unit 211 is distributed oppositely to the redistribution layer 31 on the surface of the second chip unit 212, and the connection pad 32 on the surface of the first chip unit 211 is also distributed oppositely to the connection pad 32 on the surface of the second chip unit 212.

It is to be noted that, the manner of forming the second conductive bump 34 is similar to the manner of forming the first conductive bump 33. The second conductive bump 34 may be formed by referring to the manner of forming the first conductive bump 33. The process of forming the second conductive bump 34 is not described again herein.

As shown in FIG. 8, in S140, the wire is formed. One end of the wire is connected to the conductive structure, and the other end extends outside the chip units and is connected to the external circuit.

One end of the wire 4 may be connected to the conductive structure 3, and the other end may extend outside the chip units 21 and be connected to the external circuit 11 on the substrate 1. For example, the wire 4 may be connected to the connection pad 32 in a contact manner. The data signal in the chip unit 21 may be transmitted to the external circuit 11 by means of the wire 4, the connection pad 32, the redistribution layer 31 and the first conductive bump 33. In some embodiments of the disclosure, two ends of the wire 4 may be respectively connected to the external circuit 11 on the substrate 1 and the conductive structure 3 by welding. For example, one end of the wire 4 may be welded with the connection pad 32 of the conductive structure 3, and the other end of the wire is welded with the external circuit 11.

In some embodiments of the disclosure, the wire 4 may be connected to the conductive structure 3 on the surface of one of the chip units 21 in the chip set 2. Since the chip units 21 in the chip set 2 are electrically connected to each other, data in the plurality of different chip units 21 can be transmitted to one same chip unit 21. By connecting the wire 4 and the conductive structure 3 on the surface of such a chip unit 21, an electrical signal in the chip unit 21 can be transmitted to the wire 4 by means of the conductive structure 3, so that the chip unit 21 can be connected to the external circuit 11 by means of the wire 4, so as to achieve signal transmission. In this process, signals in the plurality of chip units 21 in the chip set 2 can be simultaneously transmitted to the external circuit 11 by using one wire 4, so that signal transmission delay of different chip units 21 in the dame chip set 2 can be avoided.

The wire 4 may be made of a conductive material. For example, the wire may be made of a metal material such as gold, silver, copper and aluminum, or may be alloy composed of two or more materials. Also, the wire may be made of other metals with good conductive performance, which is not specifically limited herein. Also, the wire 4 may be made of other materials, for example, may be a non-metallic material such as polysilicon, which is not enumerated herein.

In an exemplary embodiment of the disclosure, the operation that the chip set 2 is formed on the side of the substrate 1 may further include that a connection portion 5 is formed on a surface of the first conductive bump 33. The connection portion 5 may be disposed between two adjacent ones of the chip units 21, and may be connected to the first conductive bumps 33 on the surfaces of two adjacent ones of the chip units 21 in a contact manner. For example, where the chip set 2 includes the first chip unit 211 and the second chip unit 212, the connection portion 5 is located between the first conductive bump 33 on the surface of the first chip unit 211 and the second conductive bump 34 on the surface of the second chip unit 212. The first conductive bump 33, the connection portion 5 and the second conductive bump 34 separate the first chip unit 211 and the second chip unit 212 by the preset distance.

For example, where the chip set 2 includes first chip unit 211 and the second chip unit 212, the connection portion 5 may be located between the first conductive bump 33 and the second conductive bump 34, and may be connected to the first conductive bump 33 and the second conductive bump 34 in a contact manner. The connection portion 5 may be connected to the second conductive bump 34 on the surface of the second chip unit 212 by welding, and then, the first conductive bump 33 on the surface of the first chip unit 211 is welded with the connection portion 5.

In some embodiments of the disclosure, the connection portion 5 may be made of a conductive material. For example, the material may be a soldering material that is composed of at least one of materials such as tin, lead, silver, copper, nickel, zinc, bismuth, indium, gold, cadmium, germanium or silicon. A shape of the connection portion may be hemispherical, spherical, ellipsoidal, cylindrical, cuboid, or the like. The first chip unit 211 may be electrically connected to the second chip unit 212 by means of the first conductive bump 33, the connection portion 5 and the second conductive bump 34.

It is to be noted that, where the chip set 2 includes the plurality of chip units 21, a “sandwich” structure that is composed of the first conductive bump 33, the connection portion 5 and the second conductive bump 34 may be disposed between two adjacent ones of the chip units 21. The two adjacent ones of the chip units 21 in the chip set 2 may be electrically connected to each other by means of the “sandwich” structure between the two adjacent ones of the chip units 21.

For example, the first conductive bump 33 and the connection portion 5 may be disposed on the surface of the first chip unit 211 on which the circuit module is disposed; and only the second conductive bump 34 is disposed on the surface of the second chip unit 212 on which the circuit module is disposed. Alternatively, the second conductive bump 34 and the connection portion 5 are disposed on the surface of the second chip unit 212 on which the circuit module is disposed; and only the first conductive bump 33 is disposed on the surface of the first chip unit 211 on which the circuit module is disposed.

Alternatively, it is to be noted that, the conductive structure 3 may be disposed on each of two adjacent chip units 21. For example, the first conductive bump 33 and the connection portion 5 are disposed on the first chip unit 211, and the connection portion 5 and the second conductive bump 34 are disposed on the second chip unit 212. The orthographic projection of the first conductive bump 33 and the connection portion 5 on the first chip unit 211 on the substrate does not overlap with the orthographic projection of the connection portion 5 and the second conductive bump 34 on the second chip unit 212 on the substrate 1. Therefore, the first chip unit 211 can be electrically connected to the second chip unit 212 by means of the two connection portions 5 between the first chip unit 211 and the second chip unit 212.

Alternatively, it is to be noted that, the conductive structure 3 may be disposed on each of the two adjacent ones of the chip units 21. For example, the first conductive bump 33 and the second conductive bump 34 that are distributed in a staggered manner are respectively disposed on the first chip unit 211 and the second chip unit 212. Therefore, the first chip unit 211 can be electrically connected to the second chip unit 212 directly by means of the first conductive bump 33 and the second conductive bump 34.

In some embodiments of the disclosure, the first conductive bump 33, the connection portion 5 and the second conductive bump 34 may separate the adjacent chip units 21 by a preset distance. For example, where the chip set 2 includes the first chip unit 211 and the second chip unit 212, the first conductive bump 33, the connection portion 5 and the second conductive bump 34 may separate the first chip unit 211 and the second chip unit 212 by the preset distance. For the preset distance, refer to the preset distance in the above embodiments, which is not described herein again. It is to be noted that, the preset distance may be greater than longitudinal spacing required for the bending of the wire 4. The end of the wire 4 that is connected to the connection pad 32 can be bent at the preset distance that the first chip unit 211 is spaced apart from the second chip unit 212, so that the wire 4 can be prevented from being fractured, thereby enhancing product yield.

In an exemplary embodiment of the disclosure, the method for forming a semiconductor structure may further include the following operation.

At S160, an insulation filling layer 6 is formed, and the insulation filling layer fills up a gap between two adjacent ones of the chip units 21.

As shown in FIG. 3, the insulation filling layer 6 may be disposed between the two adjacent ones of the chip units 21. The insulation filling layer 6 may be formed between the two adjacent ones of the chip units 21 by means of spin-coating or coating. Therefore, the adjacent chip units 21 may be insulated and isolated by the insulation filling layer 6, so as to avoid signal crosstalk or coupling between the chip units 21.

In an exemplary embodiment of the disclosure, a material of the insulation filling layer 6 may be an insulating adhesive or a packaging adhesive. External water and oxygen can be isolated by means of the insulation filling layer 6, so that the external water and oxygen can be prevented from entering into the chip unit 21, so as to prevent the water and oxygen from corroding the internal structure of the chip unit 21, thereby prolonging the service life of the chip unit 21.

In some embodiments of the disclosure, the insulation filling layer 6 may fill up a gap between adjacent chip units 21, so that the gap between the adjacent chip units 21 can be supported by means of the insulation filling layer 6. In addition, stress between the two adjacent chip units 21 can be balanced, so that the possibility of the fracturing of the chip units 21 due to external force can be reduced, thereby enhancing product yield.

In some embodiments of the disclosure, as shown in FIG. 7, the insulation filling layer 6 in the chip set 2 may be thick. The chip units 21 may be embedded in the insulation filling layer 6. For example, after the chip set 2 is formed, the insulation filling layer 6 may be formed on a surface of a structure that is jointly formed by the substrate 1 and the chip set 2. The insulation filling layer 6 can fill up all the gaps between the adjacent chip units 21, and wrap sidewalls of the chip units 21, so that all-round isolation protection of the chip units 21 can be achieved.

In some other embodiments of the disclosure, the insulation filling layer 6 may include a plurality of insulation layers that are spaced. The number of the insulation layers may match the number of gaps between the chip units 21. For example, in a same chip set 2, the number of the insulation layers may be 1 less than the number of the chip units 21. The insulation layers may be distributed between the two adjacent chip units 21 in a one-to-one correspondence. A thickness of the insulation layer may equal the spacing between chip units 21 that are adjacent to the insulation layer. That is to say, the insulation layer may fill up the gap between the chip units 21 that are adjacent to the insulation layer.

It is to be noted that, after the structure that is jointly formed by the insulation layers and chip sets 2 is fixed on the substrate 1, an insulation material may further continuously fill a surface of a structure that is jointly formed by the insulation layers, the chip sets 2 and the substrate 1, so as to embed the chip sets 2 into the insulation material. The insulation material together with the insulation layers may form the insulation filling layer 6. The insulation material may be the same or different from the material of the insulation layer, which is not specifically limited herein. For example, both the insulation material and the material of the insulation layer may be an insulating adhesive or a packaging adhesive; alternatively, one of the insulation material and the material of the insulation layer is an insulating adhesive, and the other is a packaging adhesive.

In an exemplary embodiment of the disclosure, in order to further increase the storage capacity, there may be a plurality of chip sets 2. The plurality of chip sets 2 may be distributed in a laminated manner in the direction perpendicular to the substrate 1. For example, the number of the chip sets 2 may be 2, 3, 4, 5, 6, or 7. Also, there may be other number of chip sets, which is not specifically limited herein.

In some embodiments of the disclosure, the number of chip units 21 in different chip sets 2 may be the same. For example, the number of the chip units 21 in each chip set 2 may be 2; alternatively, the number of the chip units 21 in each chip set 2 may be 3; and alternatively, the number of the chip units 21 in each chip set 2 may be 4. Also, there may be other number of chip units 21 in the chip sets 2, which is not enumerated herein.

In some other embodiments of the disclosure, the number of the chip units 21 in different chip sets 2 may be different. For example, the number of the chip units 21 in some of the chip sets 2 is 2, and the number of the chip units 21 in other chip sets 2 is 3; and for another example, the number of the chip units 21 in some of the chip sets 2 is 3, and the number of the chip units 21 in other chip sets 2 is 4. Also, there may be other number of chip units 21 in the chip sets 2, which is not enumerated herein.

In some embodiments of the disclosure, the chip sets 2 may be disposed with each other in an insulated manner, so that data crosstalk among different chip sets 2 can be avoided. Each chip set 2 has the corresponding conductive structure 3 and the wire 4, so that data in different chip sets 2 may be transmitted to the external circuit 11 by means of different wires 4.

In some embodiments of the disclosure, the method for forming a semiconductor structure may further include the following operation.

At S170, a plurality of packaging layers 8 are formed. The packaging layers 8 are disposed at gaps between the chip sets 2 in a one-to-one correspondence, and fill up gaps between the chip sets 2.

In an exemplary embodiment of the disclosure, a material of the packaging layer 8 may be an insulating non-conductive adhesive or packaging adhesive. The packaging layer 8 can be formed between the two adjacent chip sets 2 by means of spin-coating or coating. The adjacent chip sets 2 may be insulated and isolated by means of the packaging layer 8, so that signal crosstalk or coupling between the chip sets 2 can be avoided. In addition, external water and oxygen can be isolated by means of the packaging layer 8, and thus be prevented from entering the chip set 2, so as to prevent the water and oxygen from corroding the internal structure of the chip set 2, thereby prolonging the service life of the chip set 2.

In some embodiments of the disclosure, the number of the packaging layers 8 may match the number of the chip sets 2. For example, the number of the packaging layers 8 may be 1 less than the number of the chip sets 2. The packaging layers 8 may be distributed between two adjacent chip sets 2 in a one-to-one correspondence. The orthographic projection of the packaging layer 8 on the substrate 1 may overlap with at least the orthographic projection of the chip set 2 on the substrate 1. It is to be noted that, the packaging layers 8 may also be connected together to completely wrap the chip sets 2, so that the all-round packaging of the chip sets 2 can be achieved.

In an exemplary embodiment of the disclosure, the method for forming a semiconductor structure may further include the following operation.

At S180, an adhesive layer 7 is formed between the substrate 1 and the chip set 2 closest to the substrate 1.

A material of the adhesive layer 7 may be a conductive adhesive. The chip set 2 that is closest to the substrate 1 may be pasted on the surface of the substrate 1 by means of the adhesive layer 7, so as to prevent the chip set 2 from swaying relative to the substrate 1. It is to be noted that, the orthographic projection of the adhesive layer 7 on the substrate 1 does not overlap with the external circuit 11. That is to say, the external circuit 11 may be exposed from the adhesive layer 7, so as to facilitate the connection the external circuit 11 and the wire 4. For example, the adhesive layer 7 may be located in a middle area of the substrate 1, and the orthographic projection of the adhesive layer on the substrate 1 may mutually overlap with the orthographic projection of the chip set 2 closest to the substrate 1 on the substrate 1.

In an embodiment of the disclosure, the semiconductor structure may further include a plurality of solder balls 9. The solder balls 9 may be disposed on a side of the substrate 1 away from the chip set 2. The electrical signal in the chip unit 21 may be transmitted to an external circuit by means of the solder balls 9.

It is to be noted that, although the various operations of the method for forming a semiconductor structure in the disclosure are described in a particular order in the figure, this does not require or imply that the operations must be performed in the particular order, or that all shown operations must be performed to achieve desired results. Additionally or alternatively, certain operations may be omitted, a plurality of operations may be combined into one operation for execution, and/or one operation may be decomposed into a plurality of operations for execution, and the like.

An embodiment of the disclosure further provides a memory. The memory may include the semiconductor structure in any of the above embodiments. The specific details, formation process and beneficial effects of the memory have been described in detail in the corresponding semiconductor structure and the method for forming a semiconductor structure, which are not be described herein again.

For example, the memory may be a DRAM, an SRAM, or the like. Also, the memory may be other storage apparatuses, which is not listed herein.

Other implementation modes of the disclosure will readily occur to those skilled in the art upon consideration of the specification and practice of the invention disclosed herein. The disclosure is intended to cover any variations, uses, or adaptations of the disclosure that follow the general principles of the disclosure and include common knowledge or techniques in the technical field that are not disclosed by the disclosure. The specification and examples are to be regarded as exemplary only, with the true scope and spirit of the disclosure being indicated by the appended claims.

What is claimed is:

1. A semiconductor structure, comprising:
a substrate, comprising an external circuit;
a chip set, disposed at one side of the substrate and comprising a plurality of chip units that are spaced in a direction perpendicular to the substrate, wherein the chip units are electrically connected to each other;
a conductive structure, disposed on a surface of at least one of the chip units; and
a wire, wherein one end of the wire is connected to the conductive structure, and another end extends outside of the chip units and is connected to the external circuit.

2. The semiconductor structure of claim 1, wherein the conductive structure comprises:
a redistribution layer, disposed on the surface of the at least one of the chip units;
a connection pad, disposed on a surface of a chip unit on which the redistribution layer is formed and connected to a side of the redistribution layer close to an edge of the chip unit, wherein the wire is connected to the connection pad in a contact manner; and
a first conductive bump, disposed on the surface of the chip unit and connected to the redistribution layer in a contact manner, wherein an orthographic projection of the first conductive bump on the substrate does not overlap with an orthographic projection of the connection pad on the substrate.

3. The semiconductor structure of claim 2, wherein the conductive structure is located on a surface of a chip unit closest to the substrate in the chip set.

4. The semiconductor structure of claim 2, wherein the chip set comprises a first chip unit and a second chip unit that are in mirror arrangement; the second chip unit is located at a side of the first chip unit away from the substrate; and the conductive structure is disposed on a surface of the first chip unit close to the second chip unit.

5. The semiconductor structure of claim 4, wherein a surface of the second chip unit close to the first chip unit is provided with a second conductive bump; the second conductive bump is disposed oppositely to the first conductive bump; and the chip set further comprises:
a connection portion, located between the first conductive bump and the second conductive bump, wherein the first conductive bump, the connection portion and the second conductive bump separate the first chip unit and the second chip unit by a preset distance.

6. The semiconductor structure of claim 1, further comprising:
an insulation filling layer, filling a gap between two adjacent ones of the chip units.

7. The semiconductor structure of claim 1, wherein there are a plurality of chip sets; the plurality of chip sets are distributed in a laminated manner in the direction perpendicular to the substrate; the chip sets are insulated from each other; and each of the chip sets has a corresponding conductive structure and a corresponding wire.

8. The semiconductor structure of claim 7, further comprising:
an adhesive layer, disposed between the substrate and a chip set closest to the substrate.

9. The semiconductor structure of claim 7, further comprising:
a plurality of packaging layers, disposed at gaps between the chip sets in a one-to-one correspondence and filling the gaps between the chip sets.

10. A method for forming a semiconductor structure, comprising:
providing a substrate, wherein the substrate comprises an external circuit;
forming a chip set on one side of the substrate, wherein the chip set comprises a plurality of chip units that are spaced in a direction perpendicular to the substrate, and the chip units are electrically connected to each other;
forming a conductive structure on a surface of at least one of the chip units; and
forming a wire, wherein one end of the wire is connected to the conductive structure, and another end extends outside of the chip units and is connected to the external circuit.

11. The method of claim 10, wherein the forming a conductive structure on a surface of at least one of the chip units comprises:
forming a redistribution layer on the surface of the at least one of the chip units;
forming a connection pad on a surface of a chip unit on which the redistribution layer is formed, wherein the connection pad is connected to a side of the redistribution layer close to an edge of the chip unit, and the wire is connected to the connection pad in a contact manner; and
forming a first conductive bump on the surface of the chip unit on which the redistribution layer is formed, wherein the first conductive bump is connected to the redistribution layer in a contact manner, and an orthographic projection of the first conductive bump on the substrate does not overlap with an orthographic projection of the connection pad on the substrate.

12. The method of claim 11, wherein the conductive structure is formed on a surface of a chip unit that is closest to the substrate in the chip set.

13. The method of claim 11, wherein the chip set comprises a first chip unit and a second chip unit that are in mirror arrangement; the second chip unit is formed on a side of the first chip unit away from the substrate; and the conductive structure is formed on a surface of the first chip unit close to the second chip unit.

14. The method of claim 13, further comprising:
forming a second conductive bump on a surface of the second chip unit close to the first chip unit, wherein the second conductive bump is disposed oppositely to the first conductive bump;
wherein the forming a chip set on one side of the substrate further comprises:
forming a connection portion on a surface of the first conductive bump, wherein the connection portion is located between the first conductive bump and the second conductive bump, and the first conductive bump, the connection portion and the second conductive bump separate the first chip unit and the second chip unit by a preset distance.

15. The method of claim 10, further comprising:
forming an insulation filling layer, wherein the insulation filling layer fills a gap between two adjacent ones of the chip units.

16. The method of claim 10, wherein there are a plurality of chip sets; the plurality of chip sets are distributed in a laminated manner in the direction perpendicular to the substrate; the chip sets are insulated from each other; and each of the chip sets has a corresponding conductive structure and a corresponding wire.

17. The method of claim 16, further comprising:
forming an adhesive layer between the substrate and a chip set closest to the substrate.

18. The method of claim 16, further comprising:
forming a plurality of packaging layers, wherein the packaging layers are disposed at gaps between the chip sets in a one-to-one correspondence and fill the gaps between the chip sets.

19. A memory, comprising the semiconductor structure of claim 1.
